(19) United States
(12) Patent Application Publication
(10) Pub. No.: US 2010/0223538 A1
(43) Pub. Date: Sep. 2, 2010

(54) SEMICONDUCTOR MEMORY APPARATUS AND METHOD OF DECODING CODED DATA

(75) Inventor: Kenji SAKURADA, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/622,868

(22) Filed: Nov. 20, 2009

(30) Foreign Application Priority Data
Mar. 2, 2009 (JP) 2009-048367

(51) Int. Cl. H03M 13/00

(52) U.S. Cl. 714/801

(57) ABSTRACT

A memory card including a word line control portion configured to perform control of applying intermediate voltages made up of a first intermediate voltage lower than a center voltage of four threshold voltage distributions and a second intermediate voltage higher than the center voltage to the memory cell, a logarithmic likelihood ratio table memory portion configured to store 9-level logarithmic likelihood ratios based on read voltages, and a decoder configured to perform decoding processing on the data read using the logarithmic likelihood ratio stored in the logarithmic likelihood ratio table memory portion.

### CROSS REFERENCE TO RELATED APPLICATION

This application claims the benefit of Japanese Application No. 2009-048367 filed in Japan on Mar. 2, 2009, the contents of which are incorporated herein by this reference.

### BACKGROUND OF THE INVENTION

1. Field of the invention

The present invention relates to a semiconductor memory apparatus configured to decode coded digital data and a method of decoding coded data, and more particularly, to a semiconductor memory apparatus and a method of decoding coded data configured to perform decoding through probability-based repeated calculations.

2. Description of the Related Art

In the communication field, broadcasting field and storage field such as semiconductor memories, the development regarding encoding and decoding using error correcting codes of digital data is underway.

Error correcting codes are roughly divided into algebra-based hard decision decoding codes and soft decision decoding codes using probability-based repeated calculations. Low density parity check codes (hereinafter referred to as “LDPC codes”) belonging to soft decision decoding codes becomes a focus of attention. The LDPC code was first proposed by R. G. Gallager in 1963. After that, with an increase in the code length of the LDPC code, excellent performance approaching a Shannon limit, which is a theoretical limit of code performance, has been reported.

Here, semiconductor memory apparatuses having a NAND type semiconductor memory portion realize high density data rewriting with a simple structure by erasing data in units of a plurality of memory cells, called “blocks.” On the other hand, storage of data of a plurality of bits in one memory cell or a so-called multivalue memory also greatly contributes to the realization of high density semiconductor memory apparatuses. In the multivalue memory, data is read when a threshold voltage corresponding to an amount of charge injected into a charge storage layer of the memory cell is applied to a word line. However, although the same data is stored, the threshold voltage differs from one memory cell to another due to variations at the time of manufacturing the memory cell or a situation after charge storage or the like. That is, there is a predetermined distribution in the threshold voltage of a plurality of memory cells that store the same data. The reliability of data read at a voltage in the vicinity of the center of the threshold voltage distribution is high, whereas the reliability of data read at a voltage in the vicinity of an upper limit or lower limit of the threshold voltage distribution is low.

The present applicant discloses in Japanese Patent Application Laid-Open Publication No. 2008-59679, a so-called 16-level reading method for reading data a total of 15 types of read voltage; three types of hard bit read voltage and 12 types of soft bit read voltage from a semiconductor memory apparatus having 4-value memory cells. The decoder using the 16-level reading method does not have a high processing speed, but has decoding processing with high reliability.

### BRIEF SUMMARY OF THE INVENTION

The semiconductor memory apparatus according to an embodiment of the present invention includes a memory cell configured to store N-bit data based on 2^{N} (N is a natural number equal to or greater than 2) threshold voltage distributions, a word line configured to apply read voltages to the memory cell, a word line control portion configured to perform control of applying a plurality of intermediate voltages made up of a first intermediate voltage lower than a center voltage of the threshold voltage distribution and a second intermediate voltage higher than the center voltage to the memory cell as the read voltages, a logarithmic likelihood ratio table memory portion configured to store logarithmic likelihood ratios of a plurality of levels based on the read voltages and a decoder configured to perform decoding processing on the data read at the read voltages applied by the word line control portion using the logarithmic likelihood ratio of a level corresponding to the read voltages stored in the logarithmic likelihood ratio table memory portion through probability-based repeated calculations.

Furthermore, according to a method of decoding coded data according to another embodiment of the present invention, in order to perform decoding processing on N-bit data stored in one memory cell based on 2^{N} (N is a natural number equal to or greater than 2) threshold voltage distributions through probability-based repeated calculations, a word line control portion performs control of sequentially applying a plurality of intermediate voltages between a center voltage of a threshold voltage distribution and a boundary voltage between neighboring threshold voltage distributions to the memory cell as read voltages, and the data read at the read voltages applied by the word line control portion is subjected to decoding processing using a logarithmic likelihood ratio stored in a logarithmic likelihood ratio table memory portion corresponding to the read voltages.

### BRIEF DESCRIPTION OF THE DRAWINGS

FIG. 1 is a configuration diagram illustrating a schematic configuration of a memory card according to a first embodiment;

FIG. 2 is a configuration diagram illustrating a schematic configuration of a memory card according to the first embodiment;

FIG. 3 is a diagram illustrating a relationship between threshold voltage distributions and storage data to illustrate publicly known hard decision decoding processing;

FIG. 4 is a diagram illustrating a relationship between threshold voltage distributions, storage data and a logarithmic likelihood ratio table to illustrate publicly known soft decision decoding processing 1;

FIG. 5 is a diagram illustrating a relationship between threshold voltage distributions, storage data and a logarithmic likelihood ratio table to illustrate publicly known soft decision decoding processing 2;

FIG. 6 is a diagram illustrating a relationship between threshold voltage distributions, storage data and a logarithmic likelihood ratio table to illustrate soft decision decoding processing on the memory card according to the first embodiment;

FIG. 7 is a diagram illustrating a relationship between threshold voltage distributions, storage data and a logarithmic likelihood ratio table to illustrate soft decision decoding processing on a memory card according to a second embodiment; and

FIG. 8 is a diagram illustrating a relationship between threshold voltage distributions, storage data and a logarithmic likelihood ratio table to illustrate soft decision decoding processing on a memory card according to a third embodiment.

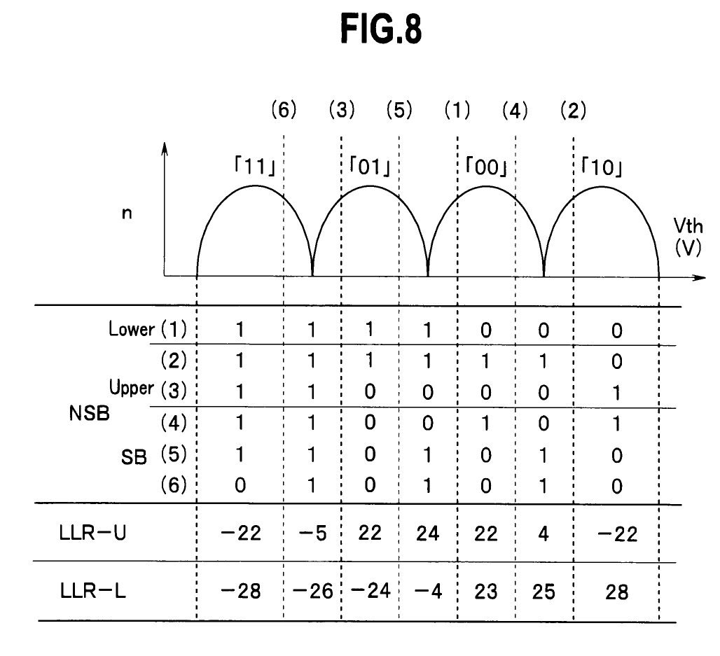

### DETAILED DESCRIPTION OF THE INVENTION

### First Embodiment

Hereinafter, a first embodiment of the present invention will be explained with reference to the attached drawings.

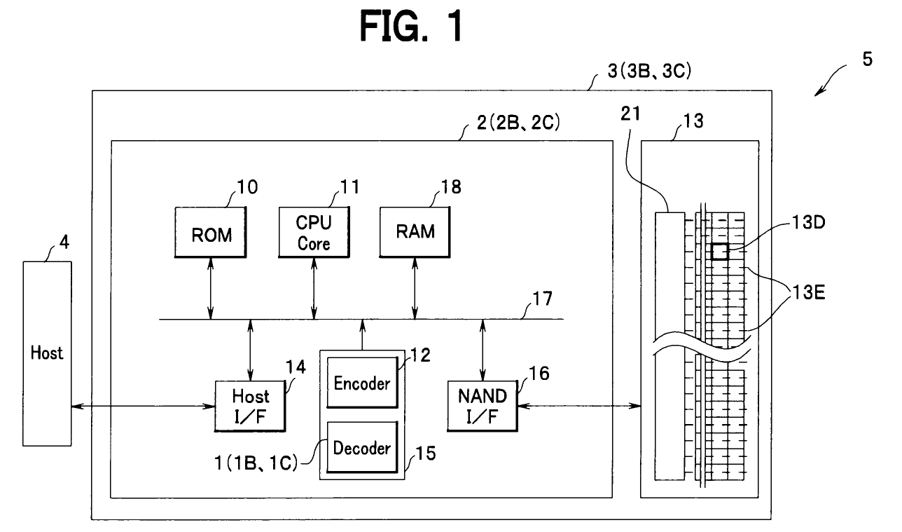

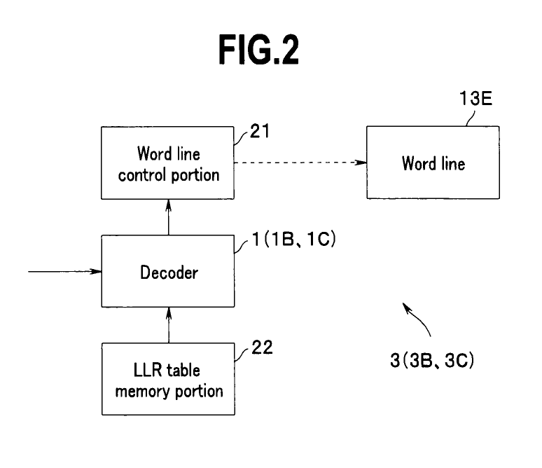

First, a schematic configuration of a memory card 3, which is a semiconductor memory apparatus according to a first embodiment of the present invention will be explained using FIG. 1 and FIG. 2.

As shown in FIG. 1, the memory card 3, which is the semiconductor memory apparatus of the present embodiment, is a storage medium configured to store data received from a host 4 such as a personal computer or digital camera and transmit the stored data to the host 4. The memory card 3 has a semiconductor memory portion (hereinafter simply referred to as “memory portion”) 13 and a memory controller 2 provided with a decoder 1. The memory portion 13 is made up of a NAND type flash memory and has a structure in which many memory cells 13D, which are unit cells, are connected via bit lines (not shown) used for writing and word lines 13E used for reading or the like. The word lines 13E are connected to a word line control portion 21. The memory cell 13D of the memory card 3 of the present embodiment is a multivalue memory cell that can store N-bit (N is a natural number equal to or greater than 2) data in one memory cell. Hereinafter, a 4-value memory cell with N=2 will be explained as an example.

The memory controller 2 has a ROM 10, a CPU core 11, a RAM 18, a host I/F (interface) 14, an error correcting (ECC: Error Correcting Code) portion 15 and a NAND I/F (interface) 16, connected together via a bus 17.

The memory controller 2 transmits/receives data to/from the host 4 via the host I/F 14 and transmits/receives data to/from the memory portion 13 via the NAND I/F 16 using the CPU core 11. Furthermore, the memory controller 2 realizes address management of the memory portion 13 through FW (firmware) executed by the CPU core 11. Furthermore, control over the entire memory card 3 is also executed by FW according to command inputs from the host 4. The ROM 10 stores a control program or the like of the memory card 3 and the RAM 18 stores an address conversion table or the like necessary for address management.

The ECC portion 15 has an encoder 12 configured to generate and add an error correcting code when data is stored and a decoder 1 configured to decode, when data is read, the coded data read. The ECC portion 15 of the decoder 1 of the present embodiment uses an LDPC code, which is an error correcting code subjected to soft decision decoding processing through probability-based repeated calculations.

Furthermore, as shown in FIG. 2, the memory card 3 has the word line control portion 21 configured to perform control of applying a predetermined read voltage to the memory cell 13D via the word line 13E, a logarithmic likelihood ratio table memory portion (LLR table memory portion) 22 configured to store a logarithmic likelihood ratio table (hereinafter also referred to as “LLR table”) made up of a logarithmic likelihood ratio (Log Likelihood Ratio, hereinafter also referred to as “LLR”) based on a read voltage and the decoder 1 configured to perform soft decision decoding processing using the logarithmic likelihood ratio.

In the decoding processing on data encoded using an LDPC code, a logarithmic likelihood ratio indicating likelihood of the data is calculated from the data read at a predetermined read voltage based on the logarithmic likelihood ratio table first. Based on the logarithmic likelihood ratio, error correcting processing through soft decision decoding processing is performed through probability-based repeated calculations.

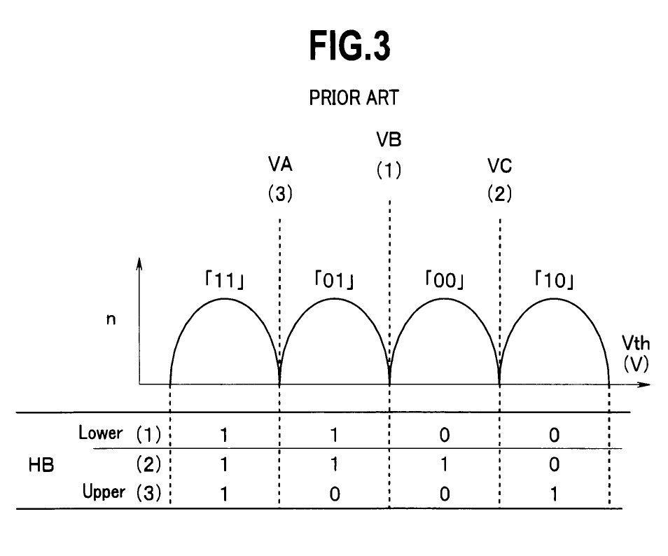

Here, for comparison, decoding processing on a publicly known memory card will be explained first using FIG. 3 to FIG. 5. In FIG. 3 or the like, the upper row is a schematic view of threshold voltage distributions, the horizontal axis shows a threshold voltage Vth and the vertical axis shows a frequency of occurrence, that is, the number of memory cells n.

### (Hard Decision Decoding Processing)

The hard decision decoding processing performs decoding processing using a parity added to a data sequence. That is, the decoder reads stored data to determine which of (11), (01), (00) and (10) corresponds thereto based on four threshold voltage distributions corresponding to four storage states of the 4-value memory cell as shown in FIG. 3. (01) means 2-bit data whose high-order bit is (0) and whose low-order bit is (1).

In the hard decision decoding processing, the word line control portion performs control of sequentially applying three types of voltages of VB, VC and VA to the word line as read voltages. That is, in FIG. 3, low-order bit data HB-Lower (1) is read through application of a VB(1) voltage and high-order bit data HB-Upper(3) is read through application of a VA(3) voltage.

The read data is a so-called hard bit (HB) and the “likelihood” of the data is unknown. Therefore, since decoding using a parity added to the data sequence is only performed in the hard decision decoding processing, it may be difficult to perform decoding processing with high reliability and deterioration of reliability may be noticeable in a multivalue memory cell in particular.

### (Soft Decision Decoding Processing 1)

In soft decision decoding processing 1, not only the hard bit but also a soft bit (SB), which is information on “likelihood” of the hard bit, is read from the memory cell. The soft decision decoding processing then performs probability-based repeated calculations, and thereby realizes decoding processing with higher reliability than the hard decision decoding processing.

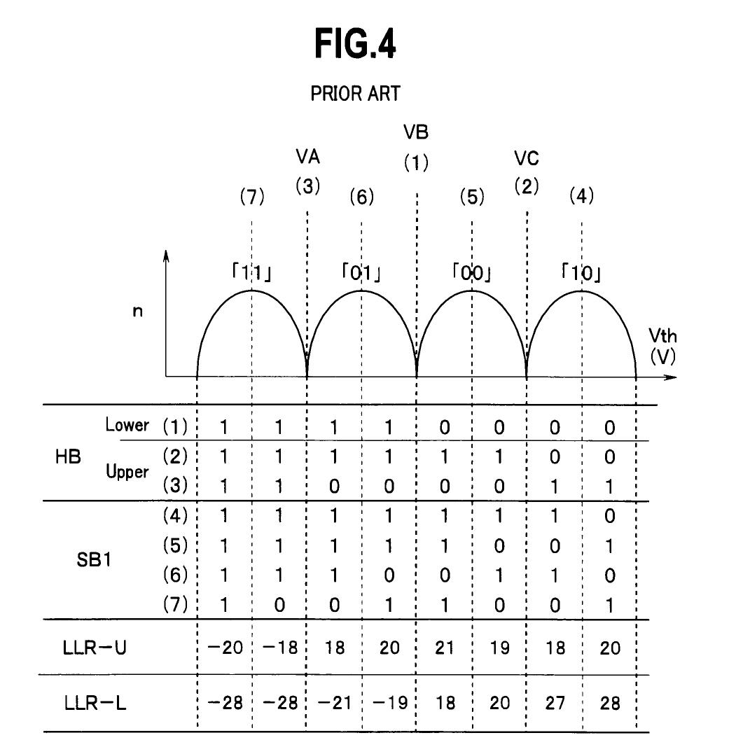

For example, in the example shown in FIG. 4, the word line control portion performs control of applying soft bit read voltages (4) to (7), which are voltages in the vicinity of centers (substantially midpoint between an upper limit voltage and a lower limit voltage) of threshold distributions of data (11), (01), (00) and (10) to the word line in addition to the hard bit read voltages VB, VC and VA. That is, the word line control portion sequentially applies seven, that is, ((2^{N}−1)+2^{N}) types of read voltages to the word line.

Therefore, the read data has three bits with one soft bit (SB) added to two hard bits (HB). The decoder then starts repeated calculations based on a logarithmic likelihood ratio table storing eight ((2^{N}−1)+2^{N}+1) levels of logarithmic likelihood ratio (Log Likelihood Ratio, hereinafter also referred to as “LLR”) indicating the likelihood of data corresponding to 3-bit data respectively.

That is, in FIG. 4, “L-LLR” indicates an LLR of a low-order bit and “U-LLR” indicates an LLR of a high-order bit. For example, the LLR of data (0) of a high-order bit of data (01) (SB1): high-order bit (0), low-order bit (1), soft bit (1) is 20 and the LLR of data (1) of a low-order bit is −19.

However, in the case of a distribution whose threshold voltage distribution is similar to a Gaussian distribution, left and right regions divided by the center of the threshold voltage distribution, that is, two regions of a low voltage region and a high voltage region are symmetric to each other. Therefore, the LLRs of the low voltage region and the high voltage regions are substantially the same, and therefore the soft decision decoding processing 1 that performs eight levels of reading may hardly improve the reliability of decoding processing.

### (Soft Decision Decoding Processing 2)

Soft decision decoding processing 2 is decoding processing disclosed by the present applicant in Japanese Patent Application Laid-Open Publication No. 2008-59679.

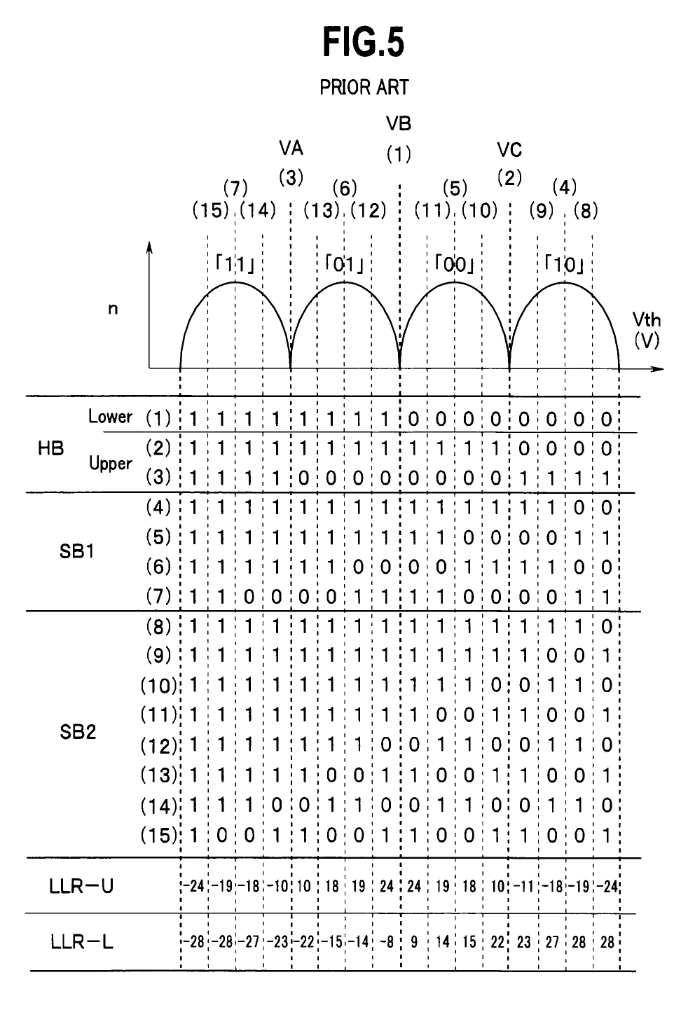

As shown in FIG. 5, a word line control portion performs control of applying soft bit 2 (SB2) read voltages (8) to (15) to a word line in addition to hard bit read voltages and soft bit 1 (SB1) read voltages (4) to (7). That is, the word line control portion sequentially applies 15, that is, ((2^{N}−1)+(3×2^{N})) types of read voltages to the word line. The soft bit 2 read voltages (8) to (15) are set so as to equidistantly divide the respective threshold distributions. That is, (i) the soft value read voltages (4), (8) and (9) are set so as to substantially equidistantly divide the threshold distribution of data (10), (ii) the soft value read voltages (5), (10) and (11) are set so as to substantially equidistantly divide the threshold distribution of data (00), (iii) the soft value read voltages (6), (12) and (13) are set so as to substantially equidistantly divide the threshold distribution of data (01) and(iv)the soft value read voltages (7), (14) and (15) are set so as to substantially equidistantly divide the threshold distribution of data (11). The soft decision decoding processing 2 calculates a logarithmic likelihood ratio from an LLR table (see FIG. 5) with 16 ((2^{N}−1)+(3×2^{N})+1) levels based on 4-bit data with further one soft bit (SB) added compared to the soft decision decoding processing 1.

The soft decision decoding processing 2 of performing 16-level reading can perform decoding processing with high reliability, but has a longer reading time to sequentially apply 15 types of read voltages to the word line and further requires two soft bits.

### (Decoding Processing Using Memory Card According to First Embodiment)

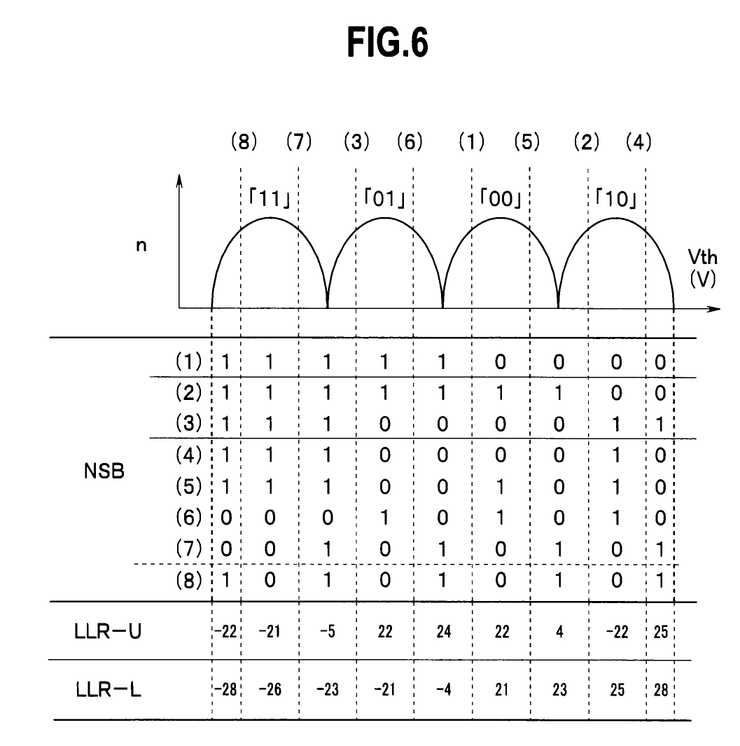

As shown in FIG. 6, the soft decision decoding processing carried out by the decoder 1 of the memory card 3 of the present embodiment performs 9-level reading and calculates a logarithmic likelihood ratio from a 9-level LLR table based on 4-bit data. That is, the word line control portion 21 performs control of sequentially applying eight, that is, (2×2^{N}) types of new soft bit (NSB) read voltages (1) to (8) to the word line 13E. The decoder 1 then performs decoding processing on the read data based on the LLR of nine (2×2^{N}+1) levels through probability-based repeated calculations.

That is, the soft decision decoding processing carried out by the decoder 1 of the memory card 3 of the present embodiment selects any one of the nine levels of logarithmic likelihood ratios from two new soft bits (NSB) corresponding to the hard bit read at read voltages (1) to (3) and two new soft bits read at read voltages (4) to (8), a total of four new soft bits (NSB).

Here, the eight types of soft bit read voltages (1) to (8) are eight (2×2²) intermediate voltages made up of a first intermediate voltage lower than the center voltage and a second intermediate voltage higher than the center voltage of the respective threshold voltage distributions. That is, in FIG. 6, the first intermediate voltage lower than the center voltage of the threshold voltage distribution corresponding to data (10) is the voltage (2) and the second intermediate voltage higher than the center voltage is the voltage (4). Likewise, the voltage (1), voltage (3) and voltage (8) are the first intermediate voltages and the voltage (5), voltage (6) and voltage (7) are the second intermediate voltages.

In FIG. 6, for explanation, the respective intermediate voltages are illustrated as if the intermediate voltages are located in the vicinity of the midpoint between the center voltage of the threshold voltage distribution and a maximum voltage or a minimum voltage of the threshold voltage distribution. However, in the decoder 1, the intermediate voltage is set based on a variation of the logarithmic likelihood ratio of data, that is, a variation of “likelihood” of data, namely, frequency of occurrence of decoding errors. That is, when the read voltage is gradually changed from the center voltage to a higher voltage or a lower voltage, the error rate drastically increases from a certain voltage. The voltage at which the error rate drastically increases is preferably set as the intermediate voltage. The memory card 3 that uses the above set read voltage can reduce the number of repeated calculations during decoding processing, and therefore provides better efficiency of decoding processing.

The logarithmic likelihood ratio table memory portion 22 may be part of the ROM 10 or RAM 18 of the memory controller 2 instead of the storage portion as a component of the encoder 1.

Since the memory card 3 sequentially applies only eight types of read voltages to the word line, the memory card 3 has a shorter reading time and can perform faster processing than the memory card configured to perform soft decision decoding processing of applying 15 types of read voltages. Moreover, the memory card 3 can perform decoding processing with high reliability equivalent to that of the memory card configured to perform the soft decision decoding processing 2 with high reliability.

The memory card 3 performs hard decision decoding processing on data of a plurality of memory cells calculated through the soft decision decoding processing, that is, a data sequence, which is a set of 2-bit data, and can thereby further increase reliability of decoding processing.

### Second Embodiment

Hereinafter, decoding processing by a memory card according to a second embodiment of the present invention will be explained with reference to the attached drawings. Since a memory card 3B of the second embodiment is similar to the memory card 3 of the first embodiment, explanations of the same components will be omitted.

In the case of the memory card 3 of the first embodiment, four new soft bits (NSB) are necessary for the memory controller 2 to perform 9-level reading. In contrast, a memory controller 2B of the memory card 3B of the second embodiment applies seven intermediate voltages as read voltages, performs 8-level reading and calculates an LLR from the logarithmic likelihood ratio table through three soft bits.

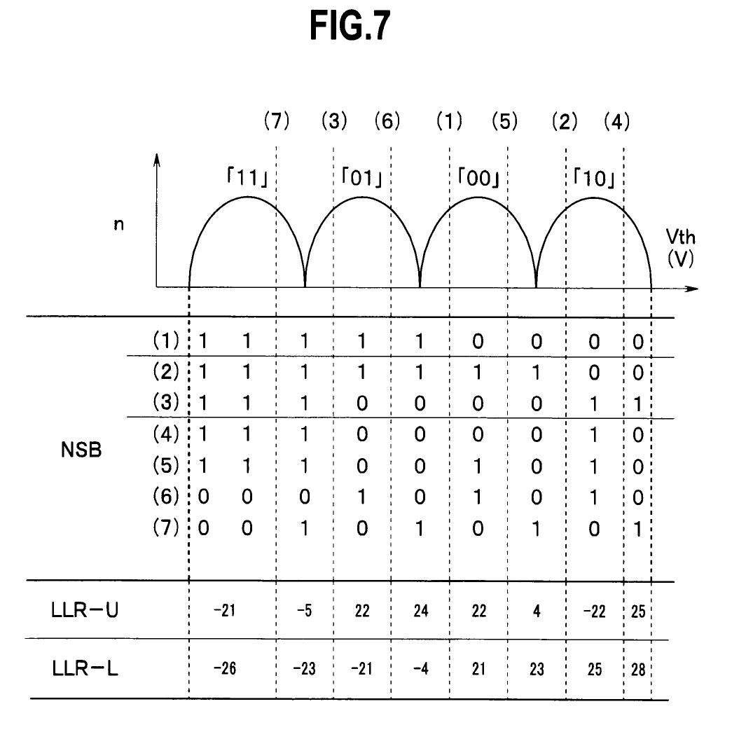

That is, as shown in FIG. 7, a decoder 1B of the memory card 3B of the second embodiment does not perform reading at the read voltage (8) in FIG. 6 used in the explanation of the first embodiment, sequentially applies 7, that is, (2×2^{N}−1) read voltages to the memory cell and performs eight (2×2^{N}) level reading.

Here, since the threshold voltage distribution corresponding to data (11) is located at an end of four threshold voltage distributions, the “likelihood” of the data is relatively high. Therefore, although the memory card 3B of the second embodiment performs 8-level reading, the memory card 3B has performance substantially equivalent to that of the decoder of 9-level reading of the first embodiment.

The memory card 3B of the second embodiment has a higher processing speed and can perform decoding processing with three soft bits, and therefore the configuration becomes simpler.

Though the decoder configured not to perform reading at the read voltage (8) on the low voltage side in FIG. 6 used in the explanation of the first embodiment was illustrated in the above explanation, a decoder configured not to perform reading at the read voltage (4) on the high voltage side can also achieve a similar effect.

### Third Embodiment

Hereinafter, decoding processing by a memory card 3C according to a third embodiment of the present invention will be explained with reference to the accompanying drawings. Since the memory card 3C of the third embodiment is similar to the memory card 3B or the like of the second embodiment, explanations of the same components will be omitted.

In the case of the memory card 3 of the first embodiment, the memory controller 2 performs 9-level reading, and therefore four new soft bits (NSB) are necessary. In contrast, in the case of the memory card 3C of the third embodiment, a memory controller 2C performs 7-level reading and calculates an LLR from the logarithmic likelihood ratio table using three new soft bits (NSB).

As explained in the explanation of the memory card 3B of the second embodiment, the “likelihood” of data located at an end of four threshold voltage distributions is relatively high. Therefore, the memory card 3C of the third embodiment has performance substantially equivalent to that of the memory card 3B of 9-level reading of the second embodiment even with seven (2×2^{N}−1) level reading whereby six types, that is, (2×2^{N}−2) types of intermediate voltages excluding the highest intermediate voltage and the lowest intermediate voltage out of (2×2^{N}) intermediate voltages between a center voltage of a threshold voltage distribution and a boundary voltage between neighboring threshold voltage distributions are applied as read voltages.

The memory card 3C of the third embodiment can perform decoding processing with three new soft bits (NSB), and therefore the configuration becomes simpler. Furthermore, since the memory card 3C of the third embodiment has only six types of read voltages sequentially applied to the memory cell, the processing speed is higher.

The decoder of the 4-value storage memory cell with N=2 or the like has been described in the above explanations as an example, but the present invention also produces effects for a decoder of a 16-value storage memory cell with N=4 such as a decoder of an 8-value storage memory cell with N=3, and rather, as N increases, the effect of the present invention becomes noticeable. That is, though N is 2 or more, the effect of the present invention is noticeable when N is 3 or more or 4 or more. The upper limit of N is 7 or less from the standpoint of industrial implementation.

Furthermore, the memory system 5 made up of the memory card 3 connected to the host 4 or the like has been described as an example, but effects similar to those of the memory card 3 or the like can also be achieved even with a so-called embedded type NAND type flash memory apparatus accommodated inside the host 4 configured to store starting data of the host 4 or the like as the memory system.

Furthermore, the code is not limited to an LDPC code as long as the code is decoded through probability-based repeated calculations and the type of decoding algorithm used can be any one of sum-product decoding, min-sum decoding and normalized min-sum decoding algorithms.

Furthermore, the decoding method of the present invention is preferably, for example, a decoding method for performing decoding processing on N-bit data to be stored in one memory cell through probability-based repeated calculations based on 2^{N} (N is a natural number equal to or greater than 2) threshold voltage distributions, including an intermediate voltage applying step of a word line control portion sequentially applying (2×2^{N}−2) intermediate voltages between a center voltage of a threshold voltage distribution and a boundary voltage between neighboring threshold voltage distributions to the memory cell as read voltages and a decoding step of performing decoding processing on the data read at the read voltages applied by the word line control portion using the logarithmic likelihood ratios stored in a logarithmic likelihood ratio table memory portion corresponding to the read voltages. N is preferably equal to or greater than 2 and equal to or less than 7.

The memory card 3 connected to the host 4 has been described as a semiconductor memory apparatus in the above explanation, but effects similar to those of the memory card 3 or the like can also be achieved by a so-called embedded type NAND type flash memory apparatus or semiconductor disk; SSD (Solid State Drive) accommodated inside the host 4 configured to record starting data of the host 4 or the like.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor memory apparatus comprising:
a memory cell configured to store N-bit data based on 2^{N} (N is a natural number equal to or greater than 2) threshold voltage distributions;
a word line configured to apply read voltages to the memory cell;
a word line control portion configured to perform control of applying a plurality of intermediate voltages made up of a first intermediate voltage lower than a center voltage of the threshold voltage distribution and a second intermediate voltage higher than the center voltage to the memory cell as the read voltages;
a logarithmic likelihood ratio table memory portion configured to store logarithmic likelihood ratios of a plurality of levels based on the read voltages; and
a decoder configured to perform decoding processing on the data read at the read voltages applied by the word line control portion using the logarithmic likelihood ratio of a level corresponding to the read voltages stored in the logarithmic likelihood ratio table memory portion through probability-based repeated calculations.

2. The semiconductor memory apparatus according to claim 1, wherein the intermediate voltages are set based on a variation of the logarithmic likelihood ratio of the data.

3. The semiconductor memory apparatus according to claim 2, wherein the decoding processing is decoding processing using an LDPC code.

4. The semiconductor memory apparatus according to claim 3, wherein the word line control portion performs control of applying (2×2^{N}) intermediate voltages, and the logarithmic likelihood ratio table stores logarithmic likelihood ratios of (2×2^{N}+1) levels.

5. The semiconductor memory apparatus according to claim 4, wherein N is equal to or greater than 2 and equal to or less than 7.

6. The semiconductor memory apparatus according to claim 3, wherein the word line control portion performs control of applying (2×2^{N}−2) intermediate voltages, and the logarithmic likelihood ratio table stores logarithmic likelihood ratios of (2×2^{N}−1) levels.

7. The semiconductor memory apparatus according to claim 6, wherein N is equal to or greater than 2 and equal to or less than 7.

8. The semiconductor memory apparatus according to claim 3, wherein the word line control portion performs control of applying (2×2^{N}−1) intermediate voltages, and the logarithmic likelihood ratio table stores logarithmic likelihood ratios of (2×2^{N}) levels.

9. The semiconductor memory apparatus according to claim 8, wherein N is equal to or greater than 2 and equal to or less than 7.

10. A method of decoding coded data,
wherein in order to perform decoding processing on N-bit data stored in one memory cell based on 2^{N} (N is a natural number equal to or greater than 2) threshold voltage distributions through probability-based repeated calculations,
a word line control portion performs control of sequentially applying a plurality of intermediate voltages between a center voltage of a threshold voltage distribution and a boundary voltage between neighboring threshold voltage distributions to the memory cell as read voltages, and
the data read at the read voltages applied by the word line control portion is subjected to decoding processing using a logarithmic likelihood ratio stored in a logarithmic likelihood ratio table memory portion corresponding to the read voltages.

11. The method of decoding coded data according to claim 10, wherein the intermediate voltages are set based on a variation of the logarithmic likelihood ratio of the data.

12. The method of decoding coded data according to claim 11, wherein the decoding processing is decoding processing using an LDPC code.

13. The method of decoding coded data according to claim 12, wherein the word line control portion performs control of applying (2×2^{N}) intermediate voltages, and the logarithmic likelihood ratio table stores logarithmic likelihood ratios of (2×2^{N}+1) levels.

14. The method of decoding coded data according to claim 13, wherein N is equal to or greater than 2 and equal to or less than 7.

15. The method of decoding coded data according to claim 12, wherein the word line control portion performs control of applying (2×2^{N}−2) intermediate voltages, and the logarithmic likelihood ratio table stores logarithmic likelihood ratios of (2×2^{N}−1) levels.

16. The method of decoding coded data according to claim 15, wherein N is equal to or greater than 2 and equal to or less than 7.

17. The method of decoding coded data according to claim 12, wherein the word line control portion performs control of applying (2×2^{N}−1) intermediate voltages, and the logarithmic likelihood ratio table stores logarithmic likelihood ratios of (2×2^{N}) levels.

18. The method of decoding coded data according to claim 17, wherein N is equal to or greater than 2 and equal to or less than 7.

19. A semiconductor memory apparatus comprising:
a memory cell configured to store 2-bit data based on four threshold voltage distributions;
an encoder configured to encode data to be written into the memory cell using an LDPC code;
a word line configured to apply read voltages to read data from the memory cell;
a word line control portion configured to perform control of sequentially applying eight intermediate voltages, based on a variation of a logarithmic likelihood ratio, made up of a first intermediate voltage lower than a center voltage of the four threshold voltage distributions and a second intermediate voltage higher than the center voltage to the memory cell as the read voltages;
a logarithmic likelihood ratio table memory portion configured to store 9-level logarithmic likelihood ratios based on the read voltages; and
a decoder configured to perform decoding processing on data read at the read voltages applied by the word line control portion using the logarithmic likelihood ratio of the level corresponding to the read voltages stored in the logarithmic likelihood ratio table memory portion through probability-based repeated calculations.
